(19) United States
(12) Patent Application Publication
(10) Pub. No.: US 2017/0118865 A1
(43) Pub. Date: Apr. 27, 2017

(54) MOBILE TERMINAL AND HEAT SINK THEREOF

(71) Applicants: LE HOLDINGS (BEIJING) CO., LTD., Beijing (CN); Lemobile Information Technology (Beijing) Co., Ltd., Beijing (CN)

(72) Inventors: Jizeng CHANG, Beijing (CN); Chengju JI, Beijing (CN)

(21) Appl. No.: 15/236,258

(22) Filed: Aug. 12, 2016

Related U.S. Application Data
(63) Continuation of application No. PCT/CN2016/088386, filed on Jul. 4, 2016.

(30) Foreign Application Priority Data
Oct. 22, 2015 (CN) 201520827631.0

(51) Int. Cl. H05K 7/20; F28F 21/04; G06F 1/20

(52) U.S. Cl. CPC H05K 7/2039; G06F 1/203; F28F 21/04; F28F 2013/001

(57) ABSTRACT

The present disclosure provides a mobile terminal and a heat sink thereof. The heat sink includes a first heat-conducting medium filled in a gap between a processor and a processor shield, a second heat-conducting medium filled in a gap between an electronic component and an electronic component shield and a third heat-conducting medium filled in a gap between the electronic component shield and a middle frame; the processor is disposed on one side, facing towards a rear casing, of a printed circuit board; heat dissipated from the processor is dissipated by a first heat dissipating channel composed of the first heat-conducting medium, the processor shield and the rear casing; heat dissipated from the processor is dissipated by a second heat dissipating channel composed of the printed circuit board, the second heat-conducting medium, the electronic component shield, the third heat-conducting medium and the middle metal frame.

### CROSS-REFERENCE TO RELATED APPLICATIONS

The present disclosure is a continuation of International Application No. PCT/CN2016/088386, filed on Jul. 4, 2016; which claims priority to Chinese Patent Application No. 201520827631.0, entitled “MOBILE TERMINAL AND HEAT SINK THEREOF”, filed to State Intellectual Property Office of The P.R.C on Oct. 22, 2015, the entire contents of all of which are incorporated herein by reference.

### FIELD OF TECHNOLOGY

The present disclosure generally relates to the field of electronic devices, and particularly relates to a mobile terminal and a heat sink thereof.

### BACKGROUND

Mobile terminal applications such as mobile phones and tablet personal computers are broadly popularized with the development of electronic technology, and are more frequently used. To satisfy a demand of a user for functions and performances, hardware of a mobile terminal is continuously upgraded, so computations it performs are more miscellaneous. As the number of cores of a CPU (Central Processing Unit) is continuously increased, dominant frequencies are increasingly high; and to enable the mobile terminal to normally run, heat dissipation of the CPU becomes particularly important.

To satisfy a demand for being portable, the mobile terminal is developed towards thinness, and a distance between the CPU and other electronic components becomes smaller. A heat dissipating space of the CPU, which is caused therewith, gets smaller, and the performance of the CPU is reduced due to temperature increment. Moreover, due to a limit of a volume of the mobile terminal, it is additionally not provided with a powerful air cooling system like to a CPU of a desktop computer, and further a huge liquid nitrogen system is impossible. The heat dissipating capability of the CPU not only affects its performance, but also influences the user holding it, and thus one doesn't want to hold a hand warmer all the time.

Therefore, at present, a technical problem urgently solved by those skilled in the art is as follows: how to increase a heat dissipating efficiency of the CPU and prevent the CPU from overheating in a case where a thickness of the mobile terminal is not increased.

### SUMMARY

An embodiment of the present disclosure discloses a mobile terminal and a heat sink thereof, which are used for solving the technical problem of lower heat dissipating speed of a CPU in a case where the thickness of the mobile terminal is not increased in the prior art.

According to one aspect of the present disclosure, the present disclosure discloses a heat sink of a mobile terminal, including a first heat-conducting medium, a second heat-conducting medium and a third heat-conducting medium;
the first heat-conducting medium is filled in a gap between a processor and a processor shield, the processor is disposed on one side, facing towards a rear casing, of a printed circuit board; heat dissipated from the processor is dissipated by a first heat dissipating channel composed of the first heat-conducting medium, the processor shield and the rear casing;
the second heat-conducting medium is filled in a gap between an electronic component and an electronic component shield, and the electronic component is disposed on the other side of the printed circuit board, and is opposite to the processor;
the third heat-conducting medium is filled in a gap between the electronic component shield and a middle frame; heat dissipated from the processor is dissipated by a second heat dissipating channel composed of the printed circuit board, the second heat-conducting medium, the electronic component shield, the third heat-conducting medium and the middle metal frame.

According to another aspect of the present disclosure, the present disclosure discloses a mobile terminal, including the heat sink of the mobile terminal described in any one of the above.

By means of the mobile terminal and the heat sink thereof provided by the embodiment of the present disclosure, in a case where the thickness of the mobile terminal is not increased, the first heat dissipating channel and the second heat dissipating channel may be constructed by filling the heat-conducting mediums to dissipate heat from the processor, working of the processor at a normal temperature is guaranteed, and the mobile terminal is prevented from overheating.

The foregoing illustration is only an overview of a technical solution of the present disclosure. In order to clearly illustrate the technical means of the present disclosure to ensure the present disclosure is implementable according to content of the specifications, and in order to make the above and other purposes, characteristics and advantages of the present disclosure more apparent to understand, embodiments of the present disclosure are specifically illustrated as follows.

### BRIEF DESCRIPTION OF THE DRAWINGS

In order to more clearly illustrate the technical solution in an embodiment of the present disclosure or the prior art, drawings required to be used in the description of the embodiment or the prior art will be briefly introduced in the following; it is obvious that the drawings described in the following are only related to some embodiments of the present disclosure. Other drawings may be obtained according to these drawings by those ordinarily skilled in the art without paying creative work.

FIG. 1 is a schematic structural diagram of a heat sink of a mobile terminal according to an embodiment of the present disclosure.

FIG. 2 is a schematic structural diagram of a mobile terminal according to an embodiment of the present disclosure.

For the sake of clarity, individual reference symbols in drawings are shown below:

1: first heat-conducting medium; 2: second heat-conducting medium; 3: third heat-conducting medium; 4: processor; 5: processor shield; 6: printed circuit board; 7: rear casing; 8: electronic component; 9: electronic component shield; 10: middle metal frame; 11: LCD (Liquid Crystal Display).

### DESCRIPTION OF THE EMBODIMENTS

For the purpose of making objects, technical schemes and advantages of an embodiment of the present disclosure more clear, clear and complete description will be made to technical schemes of the present disclosure in conjunction with corresponding drawings in the embodiment of the present disclosure. Obviously, the described embodiments are merely a part of the embodiments of the present disclosure and not all the embodiments. Based on the embodiments of the present disclosure, all other embodiments obtained by those ordinarily skilled in the art without paying creative work fall within the protection scope of the present disclosure.

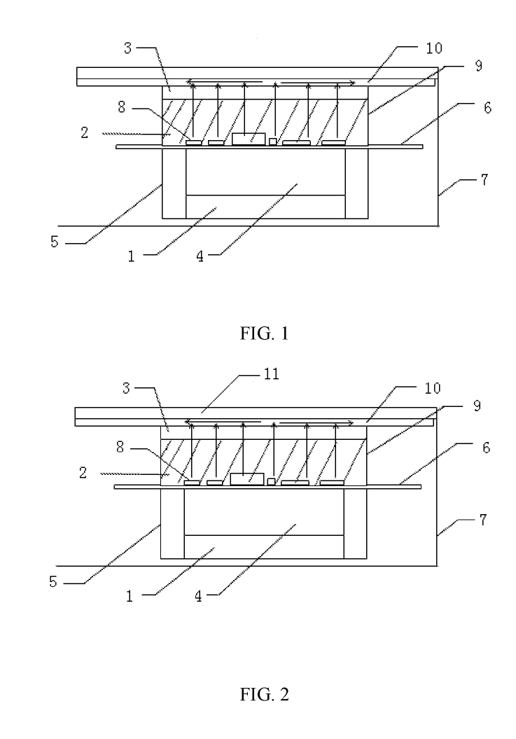

With reference to FIG. 1, a schematic structural diagram of a heat sink of a mobile terminal according to an embodiment of the present disclosure is shown.

To enable a heat dissipating speed of a CPU (Central Processing Unit) to be increased in a case where a thickness of the mobile terminal is not increased, an embodiment of the present disclosure provides a heat sink of a mobile terminal. As shown in FIG. 1, the heat sink includes:
a first heat-conducting medium 1, a second heat-conducting medium 2 and a third heat-conducting medium 3;
the first heat-conducting medium 1 is filled in a gap between a processor 4 and a processor shield 5, the processor 4 is disposed on one side, facing towards a rear casing 7, of a PCB (printed circuit board) 6;
heat dissipated from the processor 4 is dissipated by a first heat dissipating channel composed of the first heat-conducting medium 1, the processor shield 5 and the rear casing 7;
the second heat-conducting medium 2 is filled in a gap between an electronic component 8 and an electronic component shield 9, and the electronic component 8 is disposed on the other side of the printed circuit board 6, and is opposite to the processor 4;
the third heat-conducting medium 3 is filled in a gap between the electronic component shield 9 and a middle frame 10, and heat dissipated from the processor 4 is dissipated by a second heat dissipating channel composed of the printed circuit board 6, the second heat-conducting medium 2, the electronic component shield 9, the third heat-conducting medium 3 and the middle metal frame 10.

To reduce heat resistances of the gap between the processor 4 and the processor shield 5 and the gap between the electronic component 8 and the electronic component shield 9, the first heat-conducting medium 1 and the third heat-conducting medium 3 may be heat-conducting silica gels. The heat-conducting silica gels have a certain flexibility, excellent insulation, compressibility and natural surface viscidity, can fill the gap between the processor 4 and the processor shield 5 and the gap between the electronic component 8 and the electronic component shield 9, are low in heat resistance, may achieve heat transfer from the processor 4 to the processor shield 5, and may also achieve heat transfer from the processor 4 to the middle metal frame 10 through the printed circuit board 6, the second heat-conducting medium 2 and the electronic component shield 9. Meanwhile, the heat-conducting silica gels may play roles of insulation, shock absorption and the like between the processor 4 and the processor shield 5 and between the electronic component shield 9 and the middle metal frame 10, and can satisfy a design requirement of the mobile terminal for ultra-thinness.

The first heat-conducting medium 1 and the third heat-conducting medium 3 may be other filling materials with relatively low heat resistance, for example, a heat-conducting silicone grease. The heat-conducting silicone grease is a high heat-conducting and insulating organosilicon material, is almost never cured, and may keep a grease state during use for a long time at a temperature of −50° C.-+230° C. The heat-conducting silicone grease is excellent in electrical insulating property and heat conductivity.

In the embodiment of the present disclosure, the electronic component 8 may be a capacitor and/or resistor; certainly, the electronic component 8 may also be another electronic component, which is relatively low in heating value and is disposed on the printed circuit board 6 as well as corresponds to the processor 4.

To further increase a heat-conducting speed and improve a heat-dissipating effect of the processor 4, two sides of the processor shield 5 may be coated with heat-conducting coagulating slurry to reduce the heat resistance between the first heat-conducting medium 1 and the rear casing 7. Similarly, two sides of the electronic component shield may also be coated with heat-conducting coagulating slurry to reduce the heat resistance between the second heat-conducting medium 2 and the third heat-conducting medium 3 and expedite a heat-dissipating efficiency.

To increase the heat-conducting efficiency between the processor shield 5 and the rear casing 7, a graphite flake may be disposed between the processor shield 5 and the rear casing 7. The graphite flake uniformly conducts heat along two directions, and is high in heat-dissipating efficiency, small in occupation space and light in weight, and a superheat region between the processor shield 5 and the rear casing 7 may be eliminated because the graphite flake uniformly conducts heat along two directions.

In the embodiment of the present disclosure, the electronic component shield 5 and the processor shield 9 are made of an aluminum substrate, and the aluminum substrate may rapidly conduct heat to a metal base layer through an insulating layer, and then transfer the heat out by the metal base layer, thereby realizing heat dissipation of the processor 4.

By means of the heat sink of the mobile terminal, which is provided by the embodiment of the present disclosure, in a case where the thickness of the mobile terminal is not increased, the first heat dissipating channel and the second heat dissipating channel may be constructed by filling the heat-conducting mediums to dissipate heat, working of the processor at a normal temperature is guaranteed, and the mobile terminal is prevented from overheating.

FIG. 2 is a schematic structural diagram of a mobile terminal according to an embodiment of the present disclosure.

The embodiment of the present disclosure further provides a mobile terminal, as shown in FIG. 2, including the above heat sink, and further including a LCD (Liquid Crystal Display) 11 as an interface interacting with a user. The mobile terminal is a computer device used in mobile communication, and may be a mobile phone and a tablet personal computer with multiple application functions. The first heat dissipating channel and the second heat dissipating channel collectively dissipate heat from the processor, and therefore the mobile terminal is prevented from overheating caused by overheating of the processor.

Apparatus embodiments described above are illustrative only, wherein the unit described as a separate part may be or may be not physically separated, a part displayed as the unit may be or may be not a physical unit, may be located in one place, or may be distributed on a plurality of network units. Some or all of the modules may be selected to achieve the objective of the solutions of the embodiments according to actual requirements. Those ordinarily skilled in the art may understand and implement it without paying creative works.

Finally, it should be noted that the foregoing embodiments are merely illustrative of technical solutions of the present disclosure without limitation; although the present disclosure is illustrated in detail with reference to the above embodiments, those ordinarily skilled in the art will appreciate that modifications may be made on the technical solutions cited by the above embodiments, or equivalent substitutions may be made on partial technical features; moreover, these modifications or substitutions will not make the essential of corresponding technical solutions depart from the spirit and scope of the technical solutions in respective embodiments of the present disclosure.

What is claimed is:

1. A heat sink of a mobile terminal, characterized by comprising a first heat-conducting medium, a second heat-conducting medium and a third heat-conducting medium;
the first heat-conducting medium is filled in a gap between a processor and a processor shield, the processor is disposed on one side, facing towards a rear casing, of a printed circuit board; heat dissipated from the processor is dissipated by a first heat dissipating channel composed of the first heat-conducting medium, the processor shield and the rear casing;
the second heat-conducting medium is filled in a gap between an electronic component and an electronic component shield, and the electronic component is disposed on the other side of the printed circuit board, and is opposite to the processor;
the third heat-conducting medium is filled in a gap between the electronic component shield and a middle frame, and heat dissipated from the processor is dissipated by a second heat dissipating channel composed of the printed circuit board, the second heat-conducting medium, the electronic component shield, the third heat-conducting medium and the middle metal frame.

2. The heat sink according to claim 1, wherein the heat-conducting medium and the third heat-conducting medium are heat-conducting silica gels.

3. The heat sink according to claim 1, wherein the second heat-conducting medium is a heat-conducting gel.

4. The heat sink according to claim 1, wherein the electronic component is a capacitor or resistor.

5. The heat sink according to claim 1, wherein two sides of the processor shield are coated with heat-conducting coagulating slurry.

6. The heat sink according to claim 1, wherein a graphite flake is disposed between the processor shield and the rear casing.

7. The heat sink according to claim 1, wherein two sides of the electronic component shield are coated with heat-conducting coagulating slurry.

8. The heat sink according to claim 1, wherein the electronic component shield and the processor shield are made of an aluminum substrate.

9. A mobile terminal, comprising a heat sink heat sink, wherein the heat sink comprises a first heat-conducting medium, a second heat-conducting medium and a third heat-conducting medium;
the first heat-conducting medium is filled in a gap between a processor and a processor shield, the processor is disposed on one side, facing towards a rear casing, of a printed circuit board; heat dissipated from the processor is dissipated by a first heat dissipating channel composed of the first heat-conducting medium, the processor shield and the rear casing;
the second heat-conducting medium is filled in a gap between an electronic component and an electronic component shield, and the electronic component is disposed on the other side of the printed circuit board, and is opposite to the processor;
the third heat-conducting medium is filled in a gap between the electronic component shield and a middle frame, and heat dissipated from the processor is dissipated by a second heat dissipating channel composed of the printed circuit board, the second heat-conducting medium, the electronic component shield, the third heat-conducting medium and the middle metal frame.

10. The mobile terminal according to claim 9, wherein the heat-conducting medium and the third heat-conducting medium are heat-conducting silica gels.

11. The mobile terminal according to claim 9, wherein the second heat-conducting medium is a heat-conducting gel.

12. The mobile terminal according to claim 9, wherein the electronic component is a capacitor or resistor.

13. The mobile terminal according to claim 9, wherein two sides of the processor shield are coated with heat-conducting coagulating slurry.

14. The mobile terminal according to claim 9, wherein a graphite flake is disposed between the processor shield and the rear casing.

15. The mobile terminal according to claim 9, wherein two sides of the electronic component shield are coated with heat-conducting coagulating slurry.

16. The mobile terminal according to claim 9, wherein the electronic component shield and the processor shield are made of an aluminum substrate.
